(19) United States
(12) Patent Application Publication
(10) Pub. No.: US 2024/0221998 A1
(43) Pub. Date: Jul. 4, 2024

(54) COIL DEVICE

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Maki IKEBE, Osaka (JP); Koji NITTA, Osaka (JP); Yoshio OKA, Osaka (JP); Shoichiro SAKAI, Osaka (JP); Michi OGATA, Shiga (JP)

(73) Assignees: SUMITOMO ELECTRIC INDUSTRIES, LTD., Osaka (JP); SUMITOMO ELECTRIC PRINTED CIRCUITS, INC., Shiga (JP)

(21) Appl. No.: 18/288,807

(22) PCT Filed: Dec. 26, 2022
(86) PCT No.: PCT/JP2022/047958

§ 371 Date: Oct. 28, 2023

(30) Foreign Application Priority Data
Jan. 5, 2022 (JP) 2022-000508
Feb. 14, 2022 (JP) 2022-020719

(51) Int. Cl. H01F 27/32; H01F 27/29

(52) U.S. Cl. CPC H01F 27/323; H01F 27/29

(57) ABSTRACT

A coil device includes a base film that has a first principal surface and a second principal surface; a first coil wiring line that is disposed on the first principal surface and has a spirally wound portion; a second coil wiring line that is disposed on the second principal surface and has a spirally wound portion; a first protective layer that is disposed on the first principal surface to cover the first coil wiring line; a second protective layer that is disposed on the second principal surface to cover the second coil wiring line; and an electrically conductive section. A through hole is formed in the base film. The through hole extends through the base film along a thickness direction.

### TECHNICAL FIELD

The present disclosure relates to a coil device. This application claims priority to Japanese Patent Application No. 2022-508 filed on 5 Jan. 2022 and claims priority to Japanese Patent Application No. 2022-020719 filed on 14 Feb. 2022. The entire contents of the Japanese patent applications are incorporated herein by reference.

### BACKGROUND ART

For example, Japanese Patent Laying-Open No. 2016-9854 (PTL 1) describes a coil device. The coil device described in PTL 1 includes a base film, a first electrically conductive pattern, a second electrically conductive pattern, a plating layer, a first adhesive layer, a first covering film, a second adhesive layer, and a second covering film.

The base film has a first principal surface and a second principal surface. The second principal surface is the opposed surface to the first principal surface. A through hole is formed in the base film. The through hole extends through the base film in the thickness direction. The first electrically conductive pattern is spirally wound on the first principal surface. The second electrically conductive pattern is spirally wound on the second principal surface. The first electrically conductive pattern and the second electrically conductive pattern are electrically connected by the plating layer formed on the inner wall surface of a through hole.

The first adhesive layer is disposed on the first principal surface to cover the first electrically conductive pattern. The first covering film is disposed on the first adhesive layer. The second adhesive layer is disposed on the second principal surface to cover the second electrically conductive pattern. The second covering film is disposed on the second adhesive layer.

### CITATION LIST

### Patent Literature

PTL 1: Japanese Patent Laying-Open No. 2016-9854

### SUMMARY OF INVENTION

A coil device according to the present disclosure includes a base film that has a first principal surface and a second principal surface; a first coil wiring line that is disposed on the first principal surface and has a spirally wound portion; a second coil wiring line that is disposed on the second principal surface and has a spirally wound portion; a first protective layer that is disposed on the first principal surface to cover the first coil wiring line; a second protective layer that is disposed on the second principal surface to cover the second coil wiring line; and an electrically conductive section. A through hole is formed in the base film. The through hole extends through the base film along a thickness direction. The electrically conductive section is buried in the through hole and connects to the first coil wiring line and the second coil wiring line to electrically connect the first coil wiring line and the second coil wiring line. When sum of masses of the first coil wiring line, the second coil wiring line, and the electrically conductive section is defined as A and sum of volumes of the base film, the first coil wiring line, the second coil wiring line, the first protective layer, the second protective layer, and the electrically conductive section is defined as B, a value of A/B is 2.0 g/cm³ or more.

### BRIEF DESCRIPTION OF DRAWINGS

FIG. 1 is a cross-sectional view of a coil device 100.

FIG. 2 is a plan view of a printed wiring board 10.

FIG. 3 is a bottom view of printed wiring board 10.

FIG. 4 is a cross-sectional view taken along IV-IV in FIG. 2.

FIG. 5 is a flowchart illustrating a method for manufacturing printed wiring board 10.

FIG. 6 is a cross-sectional view describing seed layer formation step S2.

FIG. 7 is a cross-sectional view describing resist formation step S3.

FIG. 8 is a cross-sectional view describing first electrolytic plating step S4.

FIG. 9 is a cross-sectional view describing resist removal step S5.

FIG. 10 is a cross-sectional view describing etching step S6.

FIG. 11 is a schematic diagram describing soldering of coil device 100 to a substrate 60.

FIG. 12 is a cross-sectional view of coil device 100 according to a modification example 1.

FIG. 13 is a cross-sectional view of coil device 100 according to a modification example 2.

FIG. 14 is a cross-sectional view of coil device 100 according to a modification example 3.

### DETAILED DESCRIPTION

### Problem to be Solved by the Present Disclosure

The coil device described in PTL 1, however, has room for improvement in solderability. In other words, the coil device described in PTL 1 has room for improvement in soldering to a substrate with high levelness.

The present disclosure has been devised in view of the conventional technology as described above. More specifically, the present disclosure provides a coil device that makes it possible to improve solderability.

### Advantageous Effect of the Present Disclosure

A coil device according to the present disclosure makes it possible to improve solderability.

### DESCRIPTION OF EMBODIMENTS

First, embodiments of the present disclosure will be listed and described.

(1) A coil device according to an embodiment includes a base film that has a first principal surface and a second principal surface; a first coil wiring line that is disposed on the first principal surface and has a spirally wound portion; a second coil wiring line that is disposed on the second principal surface and has a spirally wound portion; a first protective layer that is disposed on the first principal surface to cover the first coil wiring line; a second protective layer that is disposed on the second principal surface to cover the second coil wiring line; and an electrically conductive section. A through hole is formed in the base film. The through hole extends through the base film along a thickness direction. The electrically conductive section is buried in the through hole and connects to the first coil wiring line and the second coil wiring line to electrically connect the first coil wiring line and the second coil wiring line. When sum of masses of the first coil wiring line, the second coil wiring line, and the electrically conductive section is defined as A and sum of volumes of the base film, the first coil wiring line, the second coil wiring line, the first protective layer, the second protective layer, and the electrically conductive section is defined as B, a value of A/B is 2.0 g/cm³ or more.

The coil device according to (1) makes it possible to improve solderability.

(2) The coil device according to (1) may further include: an external connection terminal that is disposed on the first protective layer; and a solder resist that is disposed on the first protective layer to expose the external connection terminal.

(3) In the coil device according to (1) or (2), the first coil wiring line, the second coil wiring line, and the electrically conductive section may each contain copper. When the sum of the volumes of the base film, the first coil wiring line, the second coil wiring line, the first protective layer, the second protective layer, and the electrically conductive section is defined as C and volume of copper contained in the first coil wiring line, the second coil wiring line, and the electrically conductive section is defined as D, a value of D/C×100 may be 10 percent or more and 70 percent or less.

(4) In the coil device according to (1) to (3), the first protective layer may include a first layer that is disposed on the first principal surface to cover the first coil wiring line and is formed by using an adhesive. The second protective layer may include a third layer that is disposed on the second principal surface to cover the second coil wiring line and is formed by using an adhesive.

(5) In the coil device according to (4), the first protective layer may further include a second layer that is disposed on the first layer. The second protective layer may further include a fourth layer that is disposed on the third layer.

(6) In the coil device according to (5), the second layer and the fourth layer may be each formed by using polyimide.

(7) In the coil device according to (4) to (6), thicknesses of the first layer and the third layer may be each 2 μm or more and 100 μm or less.

(8) In the coil device according to (1) to (7), distance between two adjacent portions of the first coil wiring line and distance between two adjacent portions of the second coil wiring line may be each 2 μm or more and 20 μm or less. Thickness of the first coil wiring line and thickness of the second coil wiring line may be each 30 μm or more and 80 μm or less. Width of the first coil wiring line and width of the second coil wiring line may be each 10 μm or more and 100 μm or less.

(9) In the coil device according to (1) to (8), a value obtained by dividing thickness of the first coil wiring line by width of the first coil wiring line and a value obtained by dividing thickness of the second coil wiring line by width of the second coil wiring line may be each 1.0 or more and 3.0 or less.

(10) In the coil device according to (1) to (9), height, width, and length of the coil device may be respectively 100 μm or more and 500 μm or less, 2 mm or more and 10 mm or less, and 2 mm or more and 40 mm or less.

(11) A coil device according to another embodiment includes a base film that has a first principal surface and a second principal surface; a first coil wiring line that is disposed on the first principal surface and has a spirally wound portion; a second coil wiring line that is disposed on the second principal surface and has a spirally wound portion; a first protective layer that is disposed on the first principal surface to cover the first coil wiring line; a second protective layer that is disposed on the second principal surface to cover the second coil wiring line; an electrically conductive section; and a dummy wiring line that is electrically separated from the first coil wiring line and the second coil wiring line and is disposed on at least any of the first principal surface and the second principal surface. A through hole is formed in the base film. The through hole extends through the base film along a thickness direction. The electrically conductive section is buried in the through hole and connects to the first coil wiring line and the second coil wiring line to electrically connect the first coil wiring line and the second coil wiring line. A value obtained by dividing sum of masses of the first coil wiring line, the second coil wiring line, the electrically conductive section, and the dummy wiring line by sum of volumes of the base film, the first coil wiring line, the second coil wiring line, the first protective layer, the second protective layer, the electrically conductive section, and the dummy wiring line is 2.0 g/cm³ or more.

The coil device according to (11) makes it possible to adjust the density by using the dummy wiring line.

### Details of Embodiments

Next, details of the embodiments of the present disclosure will be described with reference to the drawings. In the following drawings, the same or corresponding portions will be denoted by the same reference numerals and duplicate description will not be repeated.

### Configuration of Coil Device According to Embodiment

The following describes a configuration of a coil device (that will be described as “coil device 100” below) according to an embodiment.

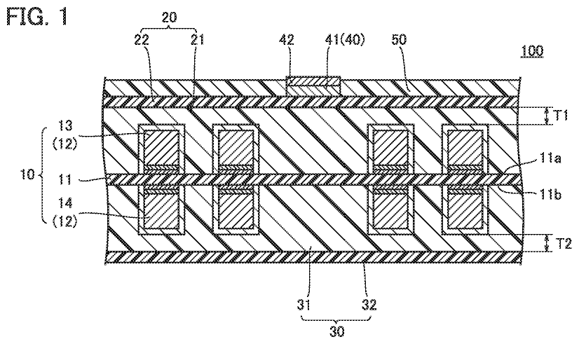

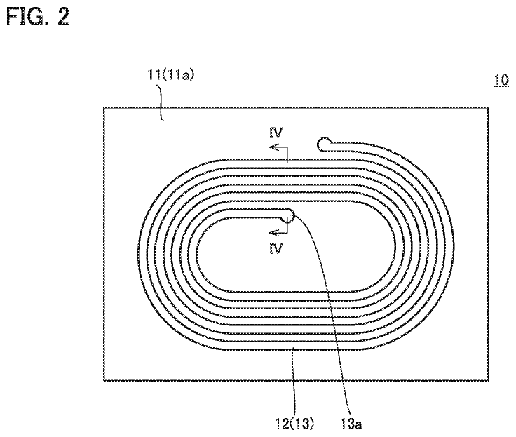

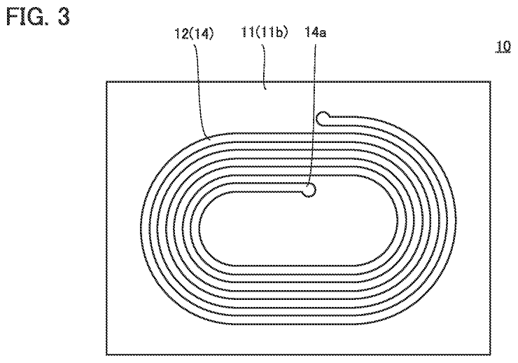

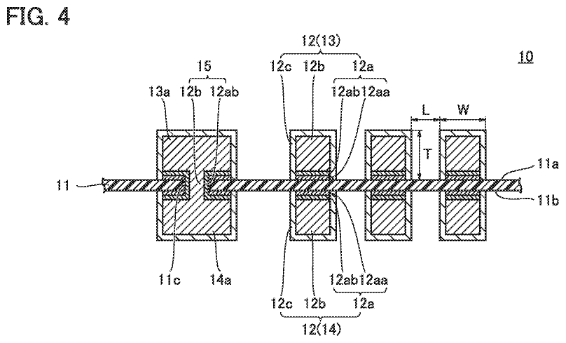

FIG. 1 is a cross-sectional view of coil device 100. FIG. 2 is a plan view of a printed wiring board 10. FIG. 3 is a bottom view of printed wiring board 10. FIG. 3 illustrates printed wiring board 10 as viewed from the opposite side to FIG. 2. FIG. 4 is a cross-sectional view taken along IV-IV in FIG. 2. As illustrated in FIGS. 1, 2, 3, and 4, coil device 100 includes printed wiring board 10, a first protective layer 20, a second protective layer 30, a wiring line 40, and a solder resist 50.

Printed wiring board 10 includes a base film 11, a coil wiring line 12, and an electrically conductive section 15.

Base film 11 has a first principal surface 11a and a second principal surface 11b. First principal surface 11a and second principal surface 11b are end faces of base film 11 in the thickness direction. Second principal surface 11b is the opposite surface to first principal surface 11a. Base film 11 is formed by using an electrically insulating material having flexibility. More specifically, base film 11 is formed by using, for example, polyimide.

A through hole 11c is formed in base film 11. Through hole 11c extends through base film 11 along the thickness direction.

Coil wiring line 12 is disposed on a principal surface of base film 11. Coil wiring line 12 includes a first coil wiring line 13 and a second coil wiring line 14. First coil wiring line 13 is disposed on first principal surface 11a. First coil wiring line 13 has a portion spirally wound along the thickness direction of base film 11 as viewed from first principal surface 11a. Second coil wiring line 14 is disposed on second principal surface 11b. Second coil wiring line 14 has a portion spirally wound along the thickness direction of base film 11 as viewed from second principal surface 11b.

Preferably, the area of the portion of first coil wiring line 13 spirally wound along the thickness direction of base film 11 as viewed from first principal surface 11a and the area of the portion of second coil wiring line 14 spirally wound along the thickness direction of base film 11 as viewed from second principal surface 11b are each 10 cm² or more and 50 cm² or less. Each of these areas is the sum of the area of the spirally wound portion and the area of a land section. The area of the spirally wound portion and the area of the land section are calculated on the basis of numerical values obtained by scanning coil device 100 with X-ray CT to figure out the dimensions and the layer configurations of the coil section and the electrically conductive section.

The distance between adjacent portions of coil wiring line 12 (first coil wiring line 13 or second coil wiring line 14) is defined as distance L. The thickness of coil wiring line 12 (first coil wiring line 13 or second coil wiring line 14) is defined as thickness T. The width of coil wiring line 12 (first coil wiring line 13 or second coil wiring line 14) is defined as width W.

It is preferable that distance L be 2 μm or more and 20 μm or less. It is preferable that thickness T be 30 μm or more and 80 μm or less. It is more preferable that thickness T be 40 μm or more and 60 μm or less. It is preferable that width W be 10 μm or more and 100 μm or less. It is more preferable that width W be 15 μm or more and 30 μm or less. It is preferable that the value obtained by dividing thickness T by width W be 1.0 or more and 3.0 or less. It is more preferable that the value obtained by dividing thickness T by width W be 1.5 or more and 2.5 or less. Thickness T, width W, and distance L of coil wiring line 12 (first coil wiring line 13 or second coil wiring line 14) are obtained by exposing a cross section of coil wiring line 12 with a section processing device such as a microtome and then averaging values measured at any ten points on the cross section.

An end section of first coil wiring line 13 serves as a land 13a. An end section of second coil wiring line 14 serves as a land 14a. Land 13a and land 14a overlap with through hole 11c. It is preferable that the difference between thickness T of land 13a and thickness T of the spirally wound portion of first coil wiring line 13 and the difference between thickness T of land 14a and thickness T of the spirally wound portion of second coil wiring line 14 be each 8 μm or less. The difference between thickness T of land 13a and thickness T of the spirally wound portion of first coil wiring line 13 and the difference between thickness T of land 14a and thickness T of the spirally wound portion of second coil wiring line 14 may be each 0 μm or more than 0 μm. The difference between thickness T of land 13a and thickness T of the spirally wound portion of first coil wiring line 13 may be 1 percent or more of thickness T of the spirally wound portion of first coil wiring line 13. The difference between thickness T of land 14a and thickness T of the spirally wound portion of second coil wiring line 14 may be 1 percent or more of thickness T of the spirally wound portion of second coil wiring line 14. Thickness T of land 13a and thickness T of land 14a are the maximum values of the thicknesses of cross sections of land 13a and land 14a exposed by a section processing device such as a microtome. Thickness T of the portion of first coil wiring line 13 and thickness T of the portion of second coil wiring line 14 are each obtained by exposing a cross section of coil wiring line 12 (first coil wiring line 13 or second coil wiring line 14) with a section processing device such as a microtome and then averaging values measured at any ten points on the cross section.

It is preferable that the length of first coil wiring line 13 and the length of second coil wiring line 14 be each 150 mm or more and 1000 mm or less. It is preferable that the sum of the length of first coil wiring line 13 and the length of second coil wiring line 14 be 300 mm or more and 2000 mm or less.

Width W of land 13a is greater than width W of the spirally wound portion of first coil wiring line 13. Width W of land 14a is greater than width W of the spirally wound portion of second coil wiring line 14.

Coil wiring line 12 (first coil wiring line 13 or second coil wiring line 14) includes a seed layer 12a, a first electrolytic plating layer 12b, and a second electrolytic plating layer 12c.

Seed layers 12a are disposed on the principal surfaces (first principal surface 11a and second principal surface 11b) of base film 11. Each of seed layers 12a includes a first layer 12aa and a second layer 12ab. First layers 12aa are disposed on the principal surfaces (first principal surface 11a and second principal surface 11b) of base film 11. Second layer 12ab is disposed on first layer 12aa. Second layer 12ab is also disposed on the inner wall surface of through hole 11c.

First layer 12aa is, for example, a sputtering layer (layer formed by sputtering). First layer 12aa is formed by using, for example, nickel-chrome alloy. Second layer 12ab is an electroless plating layer (layer formed by electroless plating). Second layer 12ab is formed by using, for example, copper.

First electrolytic plating layer 12b is a layer formed by electrolytic plating. First electrolytic plating layer 12b is formed by using copper. First electrolytic plating layer 12b is disposed on seed layer 12a. First electrolytic plating layer 12b is also disposed above the inner wall surface of through hole 11c with second layer 12ab interposed in between.

Second electrolytic plating layer 12c is a layer formed by electrolytic plating. Second electrolytic plating layer 12c is formed by using copper. Second electrolytic plating layer 12c covers seed layer 12a and first electrolytic plating layer 12b. More specifically, second electrolytic plating layer 12e is disposed on the side surfaces of seed layer 12a and the side surfaces and the upper surface of first electrolytic plating layer 12b.

Second layer 12ab and first electrolytic plating layer 12b disposed on through hole 11c serve as electrically conductive section 15. Electrically conductive section 15 electrically connects first coil wiring line 13 (land 13a) and second coil wiring line 14 (land 14a).

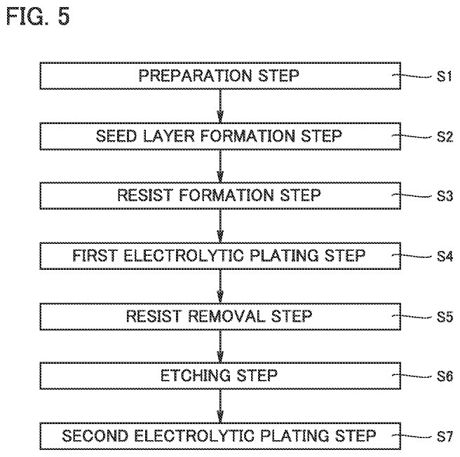

FIG. 5 is a flowchart illustrating a method for manufacturing printed wiring board 10. As illustrated in FIG. 5, the method for manufacturing printed wiring board 10 includes preparation step S1, seed layer formation step S2, resist formation step S3, first electrolytic plating step S4, resist removal step S5, etching step S6, and second electrolytic plating step S7.

In preparation step S1, base film 11 is prepared. Coil wiring line 12 is not formed in base film 11 prepared in preparation step S1. In addition, through hole 11c is not formed in base film 11 prepared in preparation step S1.

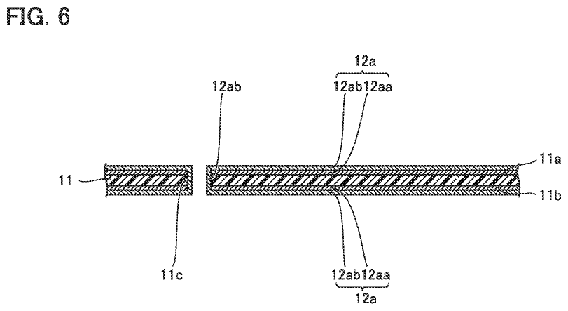

FIG. 6 is a cross-sectional view describing seed layer formation step S2. As illustrated in FIG. 6, seed layer 12a is formed in seed layer formation step S2. First, first layer 12aa is formed by sputtering in seed layer formation step S2. Second, through hole 11c is formed in seed layer formation step S2. Through hole 11c is formed by using a laser or a drill.

Third, second layer 12ab is formed by electroless plating in seed layer formation step S2. Through hole 11c is formed before the electroless plating. Thus, second layer 12ab is also formed on the inner wall surface of through hole 11c.

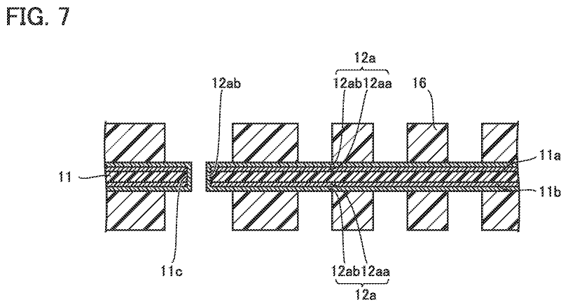

FIG. 7 is a cross-sectional view describing resist formation step S3. In resist formation step S3, a resist 16 is formed. Resist 16 is formed by applying a photosensitive organic material onto seed layer 12a and exposing the applied photosensitive organic material to light and photosensitizing it. Resist 16 may be formed by attaching a dry film resist onto seed layer 12a and exposing the attached dry resist film to light and photosensitizing it. Seed layer 12a is exposed from an opening of resist 16.

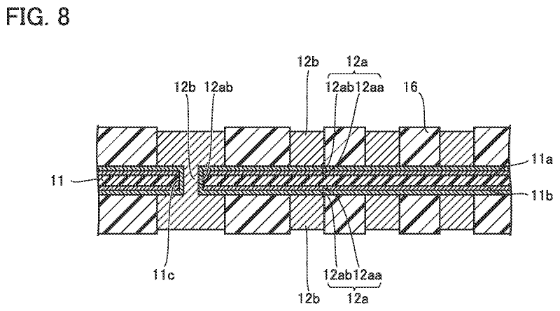

FIG. 8 is a cross-sectional view describing first electrolytic plating step S4. As illustrated in FIG. 8, in first electrolytic plating step S4, first electrolytic plating layer 12b is formed. In first electrolytic plating step S4, the supply of electricity to seed layer 12a in a plating solution grows first electrolytic plating layer 12b from seed layer 12a exposed from the opening of resist 16. It is to be noted that first electrolytic plating layer 12b is also grown in this case from second layer 12ab on through hole 11c.

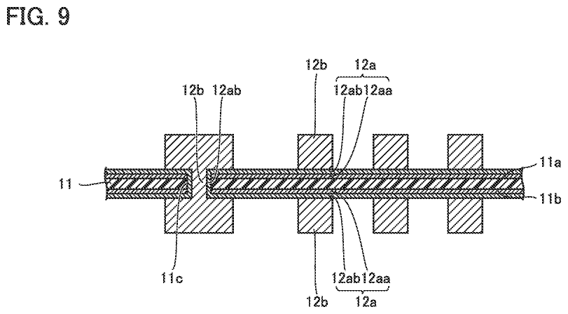

FIG. 9 is a cross-sectional view describing resist removal step S5. As illustrated in FIG. 9, resist 16 is removed in resist removal step S5. After resist 16 is removed, seed layer 12a is exposed from the region between adjacent first electrolytic plating layers 12b.

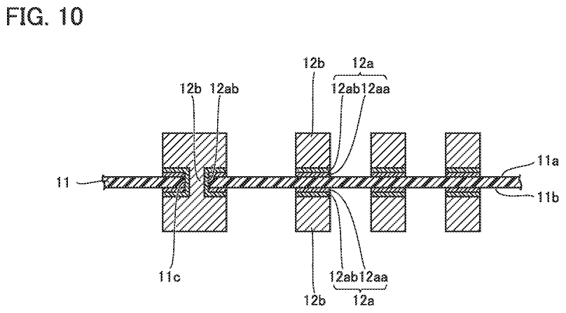

FIG. 10 is a cross-sectional view describing etching step S6. As illustrated in FIG. 10, in etching step S6, seed layer 12a is removed that is exposed from the region between adjacent first electrolytic plating layers 12b.

First, etching is performed on second layer 12ab in etching step S6. Etching is performed on second layer 12ab by supplying an etching solution between adjacent first electrolytic plating layers 12b. The etching solution is selected to control the rate of etching by a reaction between a reactive species in the etching solution and an etching target instead of the dispersion of the reactive species in the etching solution to the region near the etching target.

More specifically, as the etching solution, an etching solution is used that has a dissolution reaction rate of 1.0 μm/minute or less with respect to a material (i.e., copper) included in second layer 12ab. A specific example of the etching solution described above includes a sulfuric acid hydrogen peroxide solution or a sodium peroxodisulfate solution. It is to be noted that the dissolution reaction rate of the etching solution described above is measured on the basis of the weight of copper decreased after the etching and the etching time.

Second, etching is performed on first layer 12aa in etching step S6. The etching solutions are switched when etching is performed on first layer 12aa. As the etching solution after the switching, an etching solution is used that has a high selectivity with respect to a material (i.e., nickel-chrome alloy) included in first layer 12aa. After the etching solutions are switched, it is therefore harder for etching to proceed in first electrolytic plating layer 12b.

In second electrolytic plating step S7, second electrolytic plating layer 12c is formed. In second electrolytic plating step S7, the supply of electricity to seed layer 12a and first electrolytic plating layer 12b in a plating solution grows second electrolytic plating layer 12c to cause seed layer 12a and first electrolytic plating layer 12b to be covered. Printed wiring board 10 is thus manufactured. It is to be noted that, for example, the spouting velocity and the current density of the plating solution in second electrolytic plating step S7 are appropriately adjusted to make it possible to change the difference between thickness T of land 13a and thickness T of the spirally wound portion of first coil wiring line 13 and the difference between thickness T of land 14a and thickness T of the spirally wound portion of second coil wiring line 14.

As illustrated in FIG. 1, first protective layer 20 is disposed on first principal surface 11a to cover first coil wiring line 13. First protective layer 20 includes a first layer 21 and a second layer 22. First layer 21 is disposed on first principal surface 11a to cover first coil wiring line 13. Although not illustrated, a through hole is formed in first protective layer 20. The through hole extends through first protective layer 20 along the thickness direction and exposes first coil wiring line 13. It is to be noted that first protective layer 20 does not have to include second layer 22.

Second protective layer 30 is disposed on second principal surface 11b to cover second coil wiring line 14. Second protective layer 30 includes a third layer 31 and a fourth layer 32. Third layer 31 is disposed on second principal surface 11b to cover second coil wiring line 14. Fourth layer 32 is disposed on third layer 31. It is to be noted that second protective layer 30 does not have to include fourth layer 32.

First layer 21 and third layer 31 are each formed by using, for example, an adhesive. Second layer 22 and fourth layer 32 are each formed by using, for example, polyimide.

The thickness of first layer 21 and the thickness of third layer 31 are respectively defined as thickness T1 and thickness T2. Thickness T1 is the maximum value of the distance between the upper surface of first coil wiring line 13 and the upper surface of first layer 21. Thickness T2 is the maximum value of the distance between the upper surface of second coil wiring line 14 and the upper surface of third layer 31. It is preferable that thickness T1 and thickness T2 be each 2 μm or more and 50 μm or less. Thickness T1 and thickness T2 are each obtained by exposing a cross section of coil device 100 with a section processing device such as a microtome and then averaging values measured at any ten points on the cross section.

Wiring line 40 is disposed on first protective layer 20. Wiring line 40 is formed by using, for example, copper. Although not illustrated, wiring line 40 is electrically connected to first coil wiring line 13 by an electrically conductive section buried in the through hole formed in first protective layer 20. Wiring line 40 includes an external connection terminal 41. A plating layer 42 is disposed on external connection terminal 41. Plating layer 42 is formed by using, for example, gold. A current flows in coil wiring line 12 through external connection terminal 41. This causes coil wiring line 12 to generate a magnetic field.

Solder resist 50 is disposed on first protective layer 20 to cover wiring line 40. An opening is formed in solder resist 50. External connection terminal 41 is exposed from the opening of solder resist 50.

When the sum of the masses of first coil wiring line 13, second coil wiring line 14, and electrically conductive section 15 is defined as A and the volumes of base film 11, first coil wiring line 13, second coil wiring line 14, first protective layer 20, second protective layer 30, and electrically conductive section 15 are defined as B, the value of A/B is 2.0 g/cm³ or more. Preferably, the value of A/B is 7.0 g/cm³ or less. Preferably, it is preferable that the value of A/B be 2.2 g/cm³ or more, 3.0 g/cm³ or more, or 3.8 g/cm³ or more.

The density of copper, which is a material contained in first coil wiring line 13, second coil wiring line 14, and electrically conductive section 15, is greater than the density of polyimide, which is a material included in base film 11, second layer 22, and fourth layer 32, and the density of an adhesive that is a material included in first layer 21 and third layer 31. This increases the value obtained by dividing the sum of the masses of first coil wiring line 13, second coil wiring line 14, and electrically conductive section 15 by the sum of the volumes of base film 11, first coil wiring line 13, second coil wiring line 14, first protective layer 20, second protective layer 30, and electrically conductive section 15 as the pattern density of coil wiring line 12 increases (as width W increases and distance L decreases) and as thickness T of coil wiring line 12 increases.

First, the volumes of the respective components of coil device 100 measured by using X-ray CT are calculated to calculate the value (value of A/B) obtained by dividing the sum of the masses of first coil wiring line 13, second coil wiring line 14, and electrically conductive section 15 by the sum of the volumes of base film 11, first coil wiring line 13, second coil wiring line 14, first protective layer 20, second protective layer 30, and electrically conductive section 15. In other words, the layer configurations and the dimensions of base film 11, first coil wiring line 13, second coil wiring line 14, first protective layer 20, second protective layer 30, and electrically conductive section 15 of coil device 100 are measured and the volumes of these respective components are calculated to calculate the sum of these.

Second, the sum of the volumes of first coil wiring line 13, second coil wiring line 14, and electrically conductive section 15 is multiplied by the density of copper, which is a known value, to calculate the sum of the masses of first coil wiring line 13, second coil wiring line 14, and electrically conductive section 15.

As described above, the sum of the masses of first coil wiring line 13, second coil wiring line 14, and electrically conductive section 15 and the sum of the volumes of base film 11, first coil wiring line 13, second coil wiring line 14, first protective layer 20, second protective layer 30, and electrically conductive section 15 are obtained. This makes it possible to calculate the value (value of A/B) obtained by dividing the sum of the masses of first coil wiring line 13, second coil wiring line 14, and electrically conductive section 15 by the sum of the volumes of base film 11, first coil wiring line 13, second coil wiring line 14, first protective layer 20, second protective layer 30, and electrically conductive section 15.

In addition, when the sum of the volumes of base film 11, first coil wiring line 13, second coil wiring line 14, first protective layer 20, second protective layer 30, and electrically conductive section 15 is defined as C and the volume of copper contained in first coil wiring line 13, second coil wiring line 14, and electrically conductive section 15 is defined as D, it is preferable that the value of D/C×100 be 10 percent or more and 70 percent or less.

The height, the width, and the length of coil device 100 are respectively 100 μm or more and 500 μm or less, 2 mm or more and 10 mm or less, and 2 mm or more and 40 mm or less.

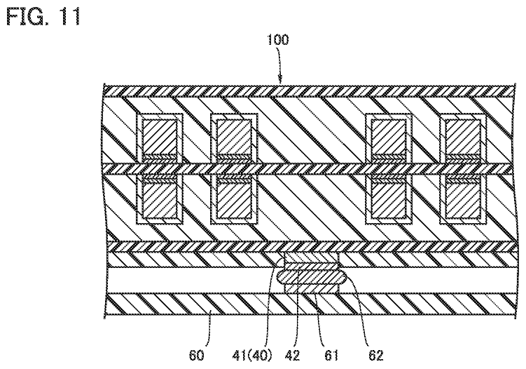

FIG. 11 is a schematic diagram describing the soldering of coil device 100 to a substrate 60. As illustrated in FIG. 11, coil device 100 is soldered, for example, to substrate 60. Substrate 60 includes a terminal 61. Terminal 61 is located on a principal surface of substrate 60. Substrate 60 is, for example, a rigid substrate. Terminal 61 is formed, by using, for example, copper. External connection terminal 41 (plating layer 42) and terminal 61 are connected by a connection layer 62 to electrically connect coil device 100 to substrate 60. Connection layer 62 is formed by using solder alloy.

### Advantageous Effect of Coil Device According to Embodiment

The following describes an advantageous effect of coil device 100.

To improve the pattern density of a coil wiring line, it is necessary to decrease the distance between adjacent portions of the coil wiring line. In addition, an increase in the thickness of the coil wiring line makes it possible to decrease the electric resistance of the coil wiring line.

An etching solution (i.e., etching solution in which the dispersion of a reactive species in the etching solution to the region near an etching target controls the rate of etching) having a high dissolution reaction rate with respect to a material included in a seed layer has been used in the past. When the distance between the adjacent portions of the coil wiring line is decreased or the thickness of the coil wiring line is increased, it is harder to supply an etching solution between the adjacent coil wiring lines.

As a result, when the etching solution as described above is used, the etching for the seed layer varies more and the amount of etching to securely remove the seed layer increases. The cause as described above has prevented the distance between the adjacent portions of the coil wiring line from being decreased and prevented the thickness of the coil wiring line from being increased in the past.

Coil device 100 includes printed wiring board 10. An etching solution having a low dissolution reaction rate with respect to a material included in second layer 12ab is used for printed wiring board 10 in etching step S6. As a result, the rate of etching in etching step S6 is controlled by a reaction between a reactive species in the etching solution and an etching target. Even when it is hard to supply an etching solution between the adjacent first electrolytic plating layers 12b, etching for seed layer 12a (second layer 12ab) is less likely to vary.

Coil device 100 therefore makes it possible to increase the pattern density and thickness T of coil wiring line 12.

In addition, width W of land 13a is greater than that of the spirally wound portion of first coil wiring line 13. Width W of land 14a is greater than that of the spirally wound portion of second coil wiring line 14. Thus, land 13a and land 14a each have a high plating growth rate and thickness T tends to increase.

When the difference between thickness T of land 13a and thickness T of the spirally wound portion of first coil wiring line 13 and the difference between thickness T of land 14a and thickness T of the spirally wound portion of second coil wiring line 14 increase, it is necessary to increase thickness T1 and thickness T2 to respectively cover first coil wiring line 13 and second coil wiring line 14 with first layer 21 and third layer 31.

However, in coil device 100, the difference between thickness T of land 13a and thickness T of the spirally wound portion of first coil wiring line 13 and the difference between thickness T of land 14a and thickness T of the spirally wound portion of second coil wiring line 14 are both small. This makes it possible to decrease thickness T1 and thickness T2.

In this way, according to coil device 100, the pattern density of coil wiring line 12 increases, thickness T increases, and thickness T1 and thickness T2 decrease. This increases the value obtained by dividing the sum of the masses of first coil wiring line 13, second coil wiring line 14, and electrically conductive section 15 by the sum of the volumes of base film 11, first coil wiring line 13, second coil wiring line 14, first protective layer 20, second protective layer 30, and electrically conductive section 15. More specifically, coil device 100 makes it possible to make 2.0 g/cm³ or more the value (value of A/B) obtained by dividing the sum of the masses of first coil wiring line 13, second coil wiring line 14, and electrically conductive section 15 by the sum of the volumes of base film 11, first coil wiring line 13, second coil wiring line 14, first protective layer 20, second protective layer 30, and electrically conductive section 15.

When coil device 100 is soldered to substrate 60, the solder alloy is fused on terminal 61. When the value obtained by dividing the sum of the masses of first coil wiring line 13, second coil wiring line 14, and electrically conductive section 15 by the sum of the volumes of base film 11, first coil wiring line 13, second coil wiring line 14, first protective layer 20, second protective layer 30, and electrically conductive section 15 is small, the surface tension of the fused solder alloy inclines coil device 100 to prevent the levelness from being secured in soldering coil device 100 to substrate 60. Coil device 100, however, has a density of 2.0 g/cm³ or more. This makes it possible to secure the levelness for the soldering to substrate 60.

Table 1 indicates a relationship between the non-defective product rate of soldering and the density of a coil device. It was determined that soldering was favorably performed when the angle between the back surface (the opposite surface to the surface on which soldering is performed) of a coil device and the front surface of a substrate fell within a range of ±3°. It is to be noted that A, B, C, D, and E are respectively described when the proportion of coil devices for which it was determined that soldering was favorably performed is 99 percent or more, when the proportion is 96 percent or more and less than 99 percent, when the proportion is 90 percent or more and less than 96 percent, when the proportion is 70 percent or more and less than 90 percent, and when the proportion is less than 70 percent. The density of a coil device in Table 1 is the value obtained by dividing the sum of the masses of first coil wiring line 13, second coil wiring line 14, and electrically conductive section 15 by the sum of the volumes of base film 11, first coil wiring line 13, second coil wiring line 14, first protective layer 20, second protective layer 30, and electrically conductive section 15.

TABLE 1

| | difference (μm) between thickness of coil | non-defective |
|---|---|---|
| density | wiring line on land and thickness of coil | product rate |
| (g/cm³) | wiring line of spirally wound portion | of soldering |
| 0.6 | 18.1 | E |
| 1.5 | 9.5 | D |
| 2.0 | 7.8 | C |
| 2.2 | 4.2 | B |
| 3.0 | 1.5 | B |
| 3.8 | 0.1 | A |

As indicated in Table 1, when the density of a coil device is less than 2.0 g/cm³, the non-defective product rate of soldering is less than 90 percent (evaluated as D or E). In contrast, when the density of a coil device is 2.0 g/cm³ or more, the non-defective product rate of soldering is 90 percent or more (evaluated as A, B, or C). This comparison even experimentally makes it clear that the solderability is improved when the density of a coil device is 2.0 g/cm³ or more.

When the value obtained by dividing the sum of the masses of first coil wiring line 13, second coil wiring line 14, and electrically conductive section 15 by the sum of the volumes of base film 11, first coil wiring line 13, second coil wiring line 14, first protective layer 20, second protective layer 30, and electrically conductive section 15 is too large, the weight of coil device 100 extrudes the solder alloy between external connection terminal 41 (plating layer 42) and terminal 61 from the region between external connection terminal 41 (plating layer 42) and terminal 61 in soldering coil device 100 to substrate 60. Once the solder alloy between external connection terminal 41 (plating layer 42) and terminal 61 is extruded, external connection terminal 41 (plating layer 42) and terminal 61 may have connection failure.

Coil device 100 therefore has a density of 7.0 g/cm³ or less to make it possible to suppress connection failure between external connection terminal 41 and terminal 61.

### Modification Example 1

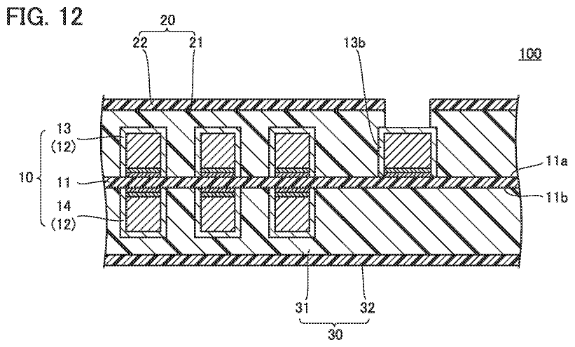

FIG. 12 is a cross-sectional view of coil device 100 according to a modification example 1. As illustrated in FIG. 12, coil device 100 does not have to include wiring line 40, plating layer 42, and solder resist 50. In this case, the opposite end section of first coil wiring line 13 to land 13a serves as a terminal section 13b. A through hole is formed in first protective layer 20 to expose terminal section 13b.

### Modification Example 2

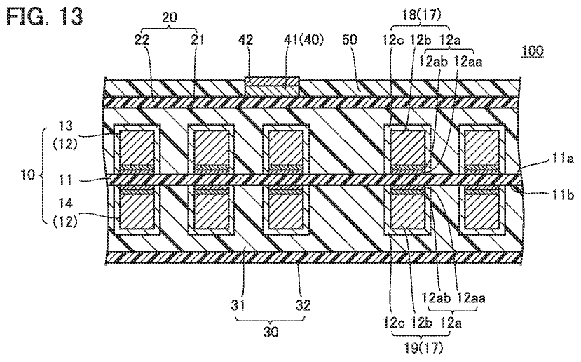

FIG. 13 is a cross-sectional view of coil device 100 according to a modification example 2. As illustrated in FIG. 13, printed wiring board 10 may include a dummy wiring line 17. Dummy wiring line 17 includes a first dummy wiring line 18 and a second dummy wiring line 19. First dummy wiring line 18 is disposed on first principal surface 11a and second dummy wiring line 19 is disposed on second principal surface 11b.

Dummy wiring line 17 is electrically separated from coil wiring line 12. More specifically, first dummy wiring line 18 is not connected to first coil wiring line 13. Second dummy wiring line 19 is not connected to second coil wiring line 14. As with coil wiring line 12, dummy wiring line 17 (first dummy wiring line 18 or second dummy wiring line 19) includes seed layer 12a, first electrolytic plating layer 12b, and second electrolytic plating layer 12c. In addition, first dummy wiring line 18 and second dummy wiring line 19 are respectively covered with first protective layer 20 (first layer 21) and second protective layer 30 (third layer 31).

When the sum of the masses of first coil wiring line 13, second coil wiring line 14, electrically conductive section 15, and dummy wiring line 17 is defined as E and the sum of the volumes of base film 11, first coil wiring line 13, second coil wiring line 14, first protective layer 20, second protective layer 30, electrically conductive section 15, and dummy wiring line 17 is defined as F, the value of E/F is 2.0 g/cm³ or more.

First, the volumes of the respective components of coil device 100 measured by using X-ray CT are calculated to calculate the value (value of E/F) obtained by dividing the sum of the masses of first coil wiring line 13, second coil wiring line 14, electrically conductive section 15, and dummy wiring line 17 by the sum of the volumes of base film 11, first coil wiring line 13, second coil wiring line 14, first protective layer 20, second protective layer 30, electrically conductive section 15, and dummy wiring line 17. In other words, the layer configurations and the dimensions of base film 11, first coil wiring line 13, second coil wiring line 14, first protective layer 20, second protective layer 30, electrically conductive section 15, and dummy wiring line 17 of coil device 100 are measured and the volumes of these respective components are calculated to calculate the sum of these.

Second, the sum of the volumes of first coil wiring line 13, second coil wiring line 14, electrically conductive section 15, and dummy wiring line 17 is multiplied by the density of copper, which is a known value, to calculate the sum of the masses of first coil wiring line 13, second coil wiring line 14, electrically conductive section 15, and dummy wiring line 17.

As described above, the sum of the masses of first coil wiring line 13, second coil wiring line 14, electrically conductive section 15, and dummy wiring line 17 and the sum of the volumes of base film 11, first coil wiring line 13, second coil wiring line 14, first protective layer 20, second protective layer 30, electrically conductive section 15, and dummy wiring line 17 are obtained. This makes it possible to calculate the value (value of E/F) obtained by dividing the sum of the masses of first coil wiring line 13, second coil wiring line 14, electrically conductive section 15, and dummy wiring line 17 by the sum of the volumes of base film 11, first coil wiring line 13, second coil wiring line 14, first protective layer 20, second protective layer 30, electrically conductive section 15, and dummy wiring line 17.

Dummy wiring line 17 also contains copper as with coil wiring line 12. The density of coil device 100 is therefore increased by forming dummy wiring line 17 in addition to coil wiring line 12. The formation of dummy wiring line 17 thus makes it possible to adjust the density of coil device 100.

### Modification Example 3

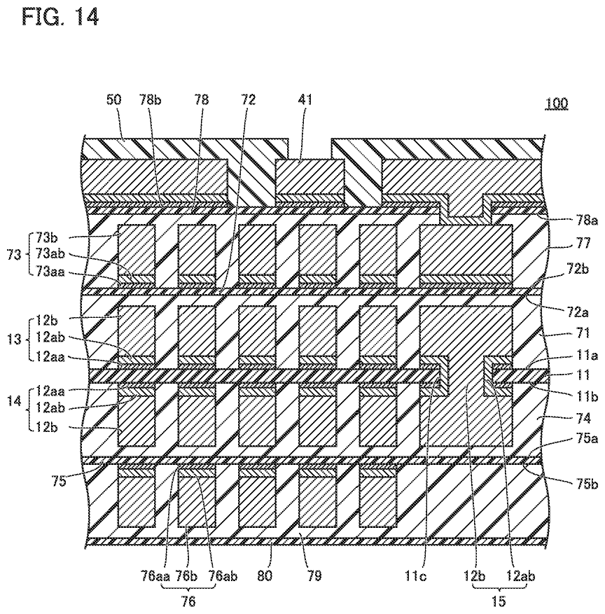

FIG. 14 is a cross-sectional view of coil device 100 according to a modification example 3. As illustrated in FIG. 14, coil device 100 may further include an adhesive layer 71, a base film 72, a third coil wiring line 73, an adhesive layer 74, a base film 75, a fourth coil wiring line 76, an adhesive layer 77, a base film 78, an adhesive layer 79, and a base film 80. Although not illustrated, coil device 100 according to modification example 3 may further include a first electrically conductive connection section and a second electrically conductive connection section.

A material included in adhesive layer 71 is an adhesive. Adhesive layer 71 is disposed on first principal surface 11a to cover first coil wiring line 13. Base film 72 is disposed on adhesive layer 71. A material included in base film 72 is, for example, polyimide. Base film 72 has a third principal surface 72a and a fourth principal surface 72b. Third principal surface 72a is opposed to adhesive layer 71 and fourth principal surface 72b is the opposite surface to third principal surface 72a.

Third coil wiring line 73 includes a seed layer and an electrolytic plating layer 73b. The seed layer includes a first layer 73aa disposed on fourth principal surface 72b and a second layer 73ab disposed on first layer 73aa. Electrolytic plating layer 73b is disposed on the seed layer. A material included in first layer 73aa and a material included in second layer 73ab are not limited. First layer 73aa and second layer 73ab respectively include, for example, nickel-chrome alloy and copper. A material included in electrolytic plating layer 73b is, for example, copper. It is to be noted that third coil wiring line 73 may further include a different electrolytic plating layer that covers the side surfaces of the seed layer and the side surfaces and the upper surface of electrolytic plating layer 73b described above and is formed by using copper.

A material included in adhesive layer 74 is an adhesive. Adhesive layer 74 is disposed on second principal surface 11b to cover second coil wiring line 14. Base film 75 is disposed on adhesive layer 74. A material included in base film 75 is, for example, polyimide. Base film 75 has a fifth principal surface 75a and a sixth principal surface 75b. Fifth principal surface 75a is opposed to adhesive layer 74 and sixth principal surface 75b is the opposite surface to fifth principal surface 75a.

Fourth coil wiring line 76 includes a seed layer and an electrolytic plating layer 76b. The seed layer includes a first layer 76aa disposed on sixth principal surface 75b and a second layer 76ab disposed on first layer 76aa. Electrolytic plating layer 76b is disposed on the seed layer. A material included in first layer 76aa and a material included in second layer 76ab are not limited. First layer 76aa and second layer 76ab respectively include, for example, nickel-chrome alloy and copper. A material included in electrolytic plating layer 76b is, for example, copper. It is to be noted that fourth coil wiring line 76 may further include a different electrolytic plating layer that covers the side surfaces of the seed layer and the side surfaces and the upper surface of electrolytic plating layer 76b described above and is formed by using copper.

A material included in adhesive layer 77 is an adhesive. Adhesive layer 77 is disposed on fourth principal surface 72b to cover third coil wiring line 73. Base film 78 is disposed on adhesive layer 77. A material included in base film 78 is, for example, polyimide. Base film 78 has a seventh principal surface 78a and an eighth principal surface 78b. Seventh principal surface 78a is opposed to adhesive layer 77 and eighth principal surface 78b is the opposite surface to seventh principal surface 78a. External connection terminal 41 is disposed on eighth principal surface 78b. A material included in adhesive layer 79 is an adhesive. Adhesive layer 79 is disposed on sixth principal surface 75b to cover fourth coil wiring line 76. Base film 80 is disposed on adhesive layer 79.

It is to be noted that first coil wiring line 13 and second coil wiring line 14 may each include second electrolytic plating layer 12c. First coil wiring line 13 and second coil wiring line 14 do not each have to include second electrolytic plating layer 12c.

As described above, coil device 100 according to modification example 3 may further include a first electrically conductive connection section and a second electrically conductive connection section that are not illustrated. A through hole (not illustrated) may be formed in base film 72. The through hole extends through base film 72 along the thickness direction. The first electrically conductive connection section is buried in the through hole formed in base film 72 and connects first coil wiring line 13 and third coil wiring line 73 to electrically connect first coil wiring line 13 and third coil wiring line 73. A through hole (not illustrated) may be formed in base film 75. The through hole extends through base film 75 along the thickness direction. The second electrically conductive connection section is buried in the through hole formed in base film 75 and connects second coil wiring line 14 and fourth coil wiring line 76 to electrically connect second coil wiring line 14 and fourth coil wiring line 76.

When the sum of the masses of first coil wiring line 13, second coil wiring line 14, electrically conductive section 15, third coil wiring line 73, fourth coil wiring line 76, the first electrically conductive connection section, and the second electrically conductive connection section is defined as G and the sum of the volumes of base film 11, first coil wiring line 13, second coil wiring line 14, electrically conductive section 15, third coil wiring line 73, fourth coil wiring line 76, adhesive layer 71, base film 72, adhesive layer 74, base film 75, adhesive layer 77, base film 78, adhesive layer 79, base film 80, the first electrically conductive connection section, and the second electrically conductive connection section is defined as H, the value of G/H is 2.0 g/cm³ or more. In other words, when coil device 100 includes a plurality of printed wiring boards, the density of coil device 100 may be 2.0 g/cm³ or more.

When the sum of the volumes of base film 11, first coil wiring line 13, second coil wiring line 14, electrically conductive section 15, third coil wiring line 73, fourth coil wiring line 76, adhesive layer 71, base film 72, adhesive layer 74, base film 75, adhesive layer 77, base film 78, adhesive layer 79, base film 80, the first electrically conductive connection section, and the second electrically conductive connection section is defined as I and the volume of copper contained in first coil wiring line 13, second coil wiring line 14, electrically conductive section 15, third coil wiring line 73, fourth coil wiring line 76, the first electrically conductive connection section, and the second electrically conductive connection section is defined as J, it is preferable that the value of J/I×100 be 10 percent or more and 70 percent or less.

A multilayer substrate including any of coil device 100 illustrated in FIG. 1 and coil device 100 according to modification example 1, modification example 2, or modification example 3 is also included in the embodiments of the present disclosure.

The embodiments disclosed herein should be understood as examples in all respects, but should not be understood as being restrictive. The scope of the present invention is demonstrated by not the embodiments described above, but CLAIMS. The scope of the present invention is intended to embrace all the modifications within the meaning and range equivalent to CLAIMS.

### REFERENCE SIGNS LIST

L distance, S1 preparation step, S2 seed layer formation step, S3 resist formation step, S4 first electrolytic plating step, S5 resist removal step, S6 etching step, S7 second electrolytic plating step, T thickness, W width, 100 coil device, 10 printed wiring board, 11 base film, 11a first principal surface, 11b second principal surface, 11c through hole, 12 coil wiring line, 12a seed layer, 12aa first layer, 12ab second layer, 12b first electrolytic plating layer, 12c second electrolytic plating layer, 13 first coil wiring line, 13a land, 13b terminal section, 14 second coil wiring line, 14a land, 15 electrically conductive section, 16 resist, 17 dummy wiring line, 18 first dummy wiring line, 19 second dummy wiring line, 20 first protective layer, 21 first layer, 22 second layer, 30 second protective layer, 31 third layer, 32 fourth layer, 40 wiring line, 41 external connection terminal, 42 plating layer, 60 substrate, 61 terminal, 62 connection layer, 50 solder resist, 71 adhesive layer, 72 base film, 72a third principal surface, 72b fourth principal surface, 73 third coil wiring line, 73aa first layer, 73ab second layer, 73b electrolytic plating layer, 74 adhesive layer, 75 base film, 75a fifth principal surface, 75b sixth principal surface, 76 fourth coil wiring line, 77 adhesive layer, 78 base film, 78a seventh principal surface, 78b eighth principal surface, 79 adhesive layer, 80 base film

1. A coil device comprising:
a base film that has a first principal surface and a second principal surface;
a first coil wiring line that is disposed on the first principal surface, the first coil wiring line having a spirally wound portion;
a second coil wiring line that is disposed on the second principal surface, the second coil wiring line having a spirally wound portion;
a first protective layer that is disposed on the first principal surface to cover the first coil wiring line;
a second protective layer that is disposed on the second principal surface to cover the second coil wiring line; and
an electrically conductive section, wherein
a through hole is formed in the base film, the through hole extending through the base film along a thickness direction,
the electrically conductive section is buried in the through hole and connects to the first coil wiring line and the second coil wiring line to electrically connect the first coil wiring line and the second coil wiring line, and
when sum of masses of the first coil wiring line, the second coil wiring line, and the electrically conductive section is defined as A and sum of volumes of the base film, the first coil wiring line, the second coil wiring line, the first protective layer, the second protective layer, and the electrically conductive section is defined as B, a value of A/B is 2.0 g/cm³ or more.

2. The coil device according to claim 1, further comprising:
an external connection terminal that is disposed on the first protective layer; and
a solder resist that is disposed on the first protective layer to expose the external connection terminal.

3. The coil device according to claim 1, wherein
the first coil wiring line, the second coil wiring line, and the electrically conductive section each contain copper, and
when the sum of the volumes of the base film, the first coil wiring line, the second coil wiring line, the first protective layer, the second protective layer, and the electrically conductive section is defined as C and the sum of volume of copper contained in the first coil wiring line, the second coil wiring line, and the electrically conductive section is defined as D, a value of D/C×100 is 10 percent or more and 70 percent or less.

4. The coil device according to claim 1, wherein
the first protective layer includes a first layer that is disposed on the first principal surface to cover the first coil wiring line, the first layer being formed by using an adhesive, and
the second protective layer includes a third layer that is disposed on the second principal surface to cover the second coil wiring line, the third layer being formed by using an adhesive.

5. The coil device according to claim 4, wherein
the first protective layer further includes a second layer that is disposed on the first layer, and
the second protective layer further includes a fourth layer that is disposed on the third layer.

6. The coil device according to claim 5, wherein the second layer and the fourth layer are each formed by using polyimide.

7. The coil device according to claim 4, wherein thicknesses of the first layer and the third layer are each 2 μm or more and 100 μm or less.

8. The coil device according to claim 1, wherein
distance between two adjacent portions of the first coil wiring line and distance between two adjacent portions of the second coil wiring line are each 2 μm or more and 20 μm or less,
thickness of the first coil wiring line and thickness of the second coil wiring line are each 30 μm or more and 80 μm or less, and
width of the first coil wiring line and width of the second coil wiring line are each 10 μm or more and 100 μm or less.

9. The coil device according to claim 1, wherein a value obtained by dividing thickness of the first coil wiring line by width of the first coil wiring line and a value obtained by dividing thickness of the second coil wiring line by width of the second coil wiring line are each 1.0 or more and 3.0 or less.

10. The coil device according to claim 1, wherein height, width, and length of the coil device are respectively 100 μm or more and 500 μm or less, 2 mm or more and 10 mm or less, and 2 mm or more and 40 mm or less.

11. A coil device comprising:
a base film that has a first principal surface and a second principal surface;
a first coil wiring line that is disposed on the first principal surface, the first coil wiring line having a spirally wound portion;
a second coil wiring line that is disposed on the second principal surface, the second coil wiring line having a spirally wound portion;
a first protective layer that is disposed on the first principal surface to cover the first coil wiring line;
a second protective layer that is disposed on the second principal surface to cover the second coil wiring line;
an electrically conductive section; and
a dummy wiring line that is electrically separated from the first coil wiring line and the second coil wiring line, the dummy wiring line being disposed on at least any of the first principal surface and the second principal surface, wherein
a through hole is formed in the base film, the through hole extending through the base film along a thickness direction,
the electrically conductive section is buried in the through hole and connects to the first coil wiring line and the second coil wiring line to electrically connect the first coil wiring line and the second coil wiring line, and
when sum of masses of the first coil wiring line, the second coil wiring line, the electrically conductive section, and the dummy wiring line is defined as E and sum of volumes of the base film, the first coil wiring line, the second coil wiring line, the first protective layer, the second protective layer, the electrically conductive section, and the dummy wiring line is defined as F, a value of E/F is 2.0 g/cm³ or more.
